(19) United States
(12) Patent Application Publication
(10) Pub. No.: US 2006/0147748 A1
(43) Pub. Date: Jul. 6, 2006

(54) Organic light emitting device

(75) Inventor: Chung-Wen Ko, Sijhih City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/141,891

(22) Filed: Jun. 1, 2005

(30) Foreign Application Priority Data
Dec. 30, 2004 (TW) 93141334

(51) Int. Cl. H01L 51/54; H05B 33/14

(52) U.S. Cl. 428/690; 428/917; 313/504; 313/506; 257/102; 257/103; 257/E51.039; 257/E51.043

(57) ABSTRACT

An organic light emitting device comprises an anode, a cathode and a complex emitting layer. The complex emitting layer comprises a host and a guest. The host has a first energy level of a valence band and is used for a hole-injection layer or hole-transport layer. The guest has a second energy level of a conduction band and is used for doping the guest. The difference between the first and second energy levels is less than 2.5 eV.

### BACKGROUND

The invention relates to a light emitting device and, in particular, to an organic light emitting device.

FIG. 1 shows a conventional organic light emitting device. Fabrication of an organic light emitting device typically comprises deposition of organic layers, such as hole-injection layer 104, hole-transport layer 106, light emitting layer 108 and electron-transport layer 110, on an anode 102. Another electrode of the opposite polarity(cathode) 102′ is plated on the organic layers. The injection of holes is closely related to energy level difference and an interface between the anode and the hole-injection layer. Hole injection and charge recombination influence device efficiency and lifetime. As a result, improving hole injection and avoiding charge accumulation at the interface between the anode and the organic layers is critical for device reliability. In addition, since thin organic layers or a rough anode surface can result in leakage or short circuits in the device and thus reduce device lifetime, increasing the thickness of the organic layers is important. Thick organic layers cause slow charge transport and higher driving voltage is required. To alleviate such problem, forming p-type or n-type doping layers by incorporating dopants into transport material enhances transport efficiency and the required driving voltage does not increase significantly as thickness of the organic layers increases. Tetrafluoro-tetracyanoquinodimethance(F4-TCNQ) is used as a p-type dopant in the hole-injection layer to enhance hole mobility to reduce required driving voltage. However, since the F4-TCNQ molecule is small, the doping concentration of F4-TCNQ must be kept low to prevent quenching or recrystallization leading to performance degradation.

### SUMMARY

Embodiments of the invention are to incorporate dopants, such as fullerene, into a hole-injection layer or a hole-transport layer to enhance hole mobility. Thus, the hole-injection layer and/or the hole-transport layer can be thickened without influencing the I-V characteristics.

An embodiment of an organic light emitting device comprises an anode, a cathode and a complex emitting layer. The complex emitting layer comprises a host and a guest. The host has a first energy level of a valence band. The host is used in a hole-injection layer or a hole-transport layer. The guest has a second energy level of a conduction band and is used to dope the host. The difference between the first and second energy levels is less than 2.5 eV.

### BRIEF DESCRIPTION OF THE DRAWINGS

FIG. 1 shows a conventional organic light emitting device.

FIG. 2 shows an organic light emitting device according to an embodiment of the invention.

FIG. 3 is a schematic diagram of energy levels of the host and the guest.

FIG. 4A compares a driving voltage with a driving current per unit area of a conventional light emitting device and a light emitting device according to an embodiment of the invention.

FIG. 4B compares brightness with driving current per unit area of a conventional light emitting device and a light emitting device according to an embodiment of the invention.

FIG. 5 compares reliability of a conventional light emitting device and a light emitting device according to an embodiment of the invention.

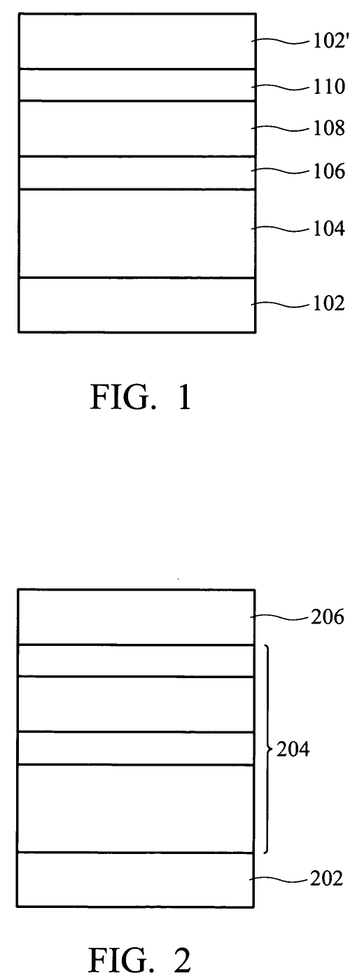

### DETAILED DESCRIPTION

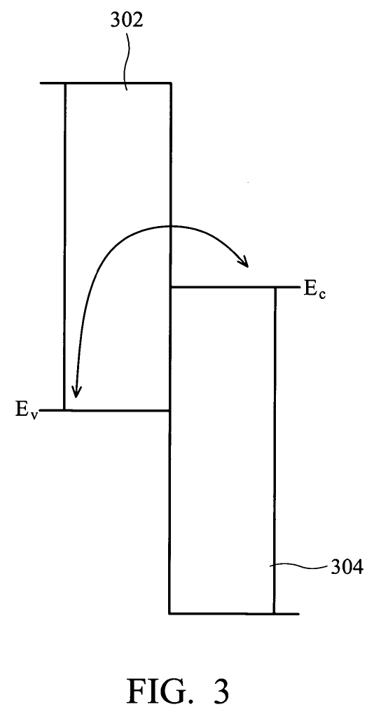

FIG. 2 shows an organic light emitting device according to an embodiment of the invention. As shown in FIG. 2, the light emitting device comprises an anode 202, a cathode 206 and a complex emitting layer 204. The complex emitting layer 204 comprises a host and a guest. The host is used in a hole-injection layer 203 or a hole-transport layer. The host is doped with the guest. The host is a material with hole-injection or hole-transport characteristic. Some examples of the host materials have functional groups of metal phthalocyanine and/or triarylamine. The compound with metal phthalocyanine, for example, is CuPc with structure of.

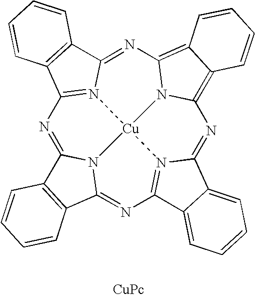

The compounds with triarylamine, for example, are MTDATA, 2T-NATA or NPB with structures of.

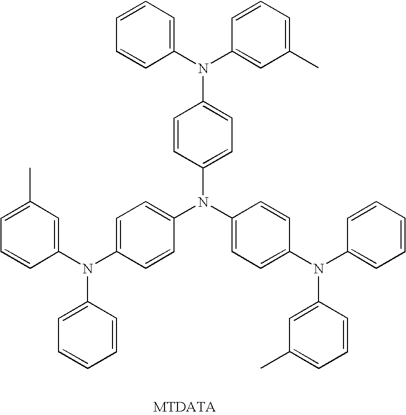

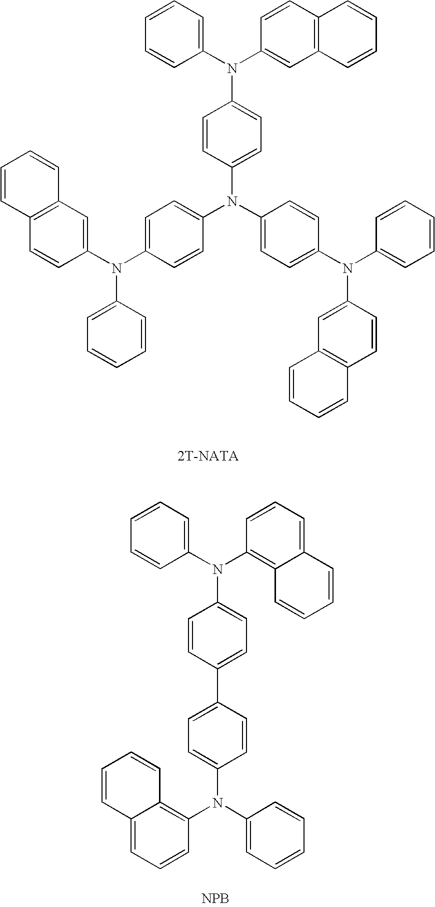

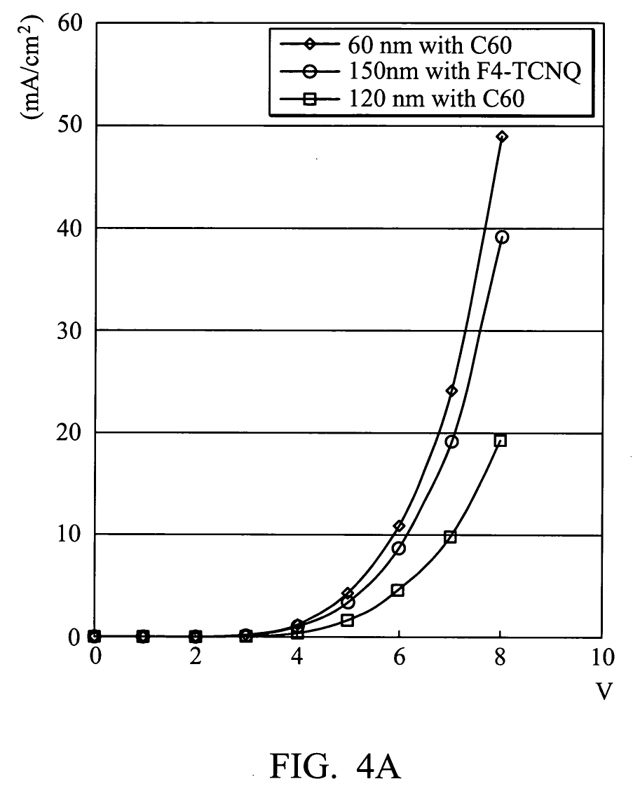

FIG. 3 is a schematic diagram of energy levels of the host 302 and the guest 304. The host has a first energy level of valence band Ev. The guest has a second energy level of conduction band Ec. In the embodiments of the invention, the difference Ec-Ev between the first and second energy levels Ec and Ev is less than 2.5 eV. The guest can be an organic material, preferably, Alq. Alternatively, the guest can be an inorganic material, such as fullerene. The fullerene comprises C60, C70, C76, C78, C82, C84, C90, C96 and the derivatives thereof. The molecular doping concentration typically ranges from 0.1% to 50%. Preferably, the molecular doping concentration ranges from 1% to 20%. The guest has a distribution depth of 5 to 500 nm in the host.

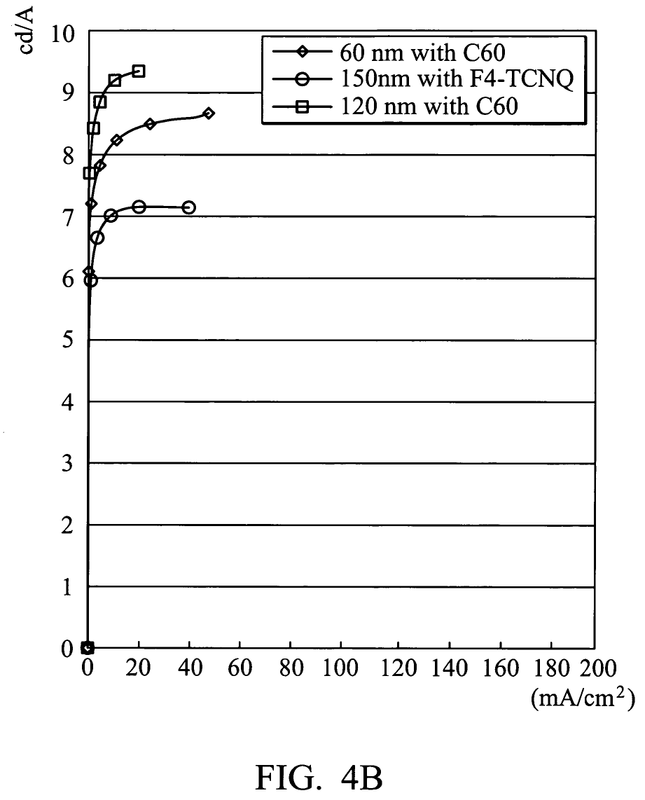

FIG. 4A compares a driving voltage with a driving current per unit area of a conventional light emitting device and a light emitting device according to an embodiment of the invention. The curve formed by diamond data points means that C60 is used as the guest and the distribution depth is 60 nm. The curve formed by round data points means that F4-TCQN is used as the guest and the distribution depth is 150 nm. The curve formed by square data points means that C60 is used as the guest and the distribution depth is 120 nm. Generally speaking, noticeable driving current is generated only when the driving voltage is higher than a threshold voltage of a light emitting device. The lower the threshold voltage, the better the performance of the light emitting device. FIG. 4A shows that the threshold voltage of the square data points is only slightly higher than round data points. The threshold voltage of the diamond data points is much lower than the round data points.

FIG. 4B compares brightness with driving current per unit area of a conventional light emitting device and a light emitting device according to an embodiment of the invention. The curve formed by diamond data points means that C60 is used as the guest and the distribution depth is 60 nm. The curve formed by round data points means that F4-TCQN is used as the guest and the distribution depth is 150 nm. The curve formed by square data points means that C60 is used as the guest and the distribution depth is 120 nm. Generally speaking, for the same driving current per unit area, the higher the brightness, the better the performance of the light emitting device. FIG. 4B shows that the brightness of the diamond and square data points is higher than the round data points. FIGS. 4A and 4B show that the light emitting device with a guest comprising C60 of 60 nm has better performance than that with a guest comprising F4-TCNQ of 150 nm.

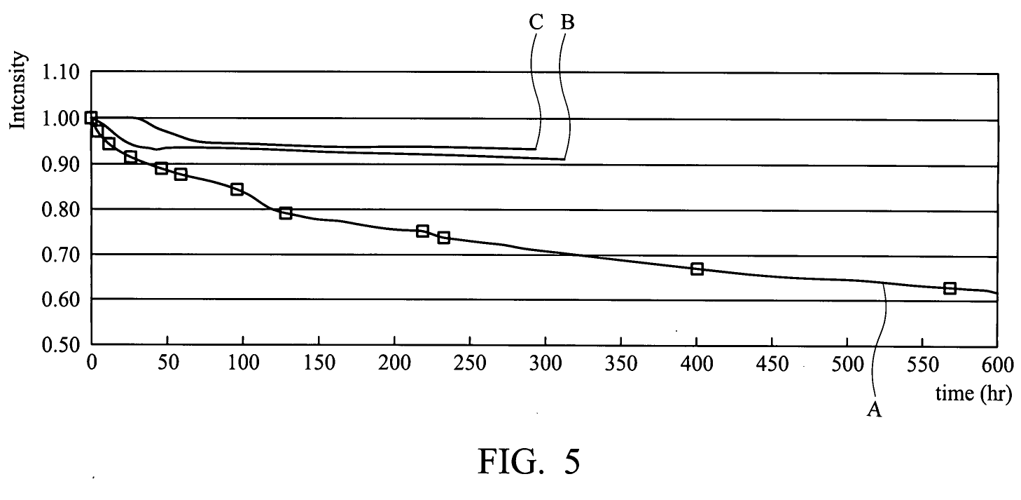

FIG. 5 compares reliability of a conventional light emitting device and a light emitting device according to an embodiment of the invention. The vertical axis of FIG. 5 represents a normalized brightness and the horizontal axis represents operating duration of the light emitting devices. The curve A means that F4-TCNQ is used as the guest and the distribution depth is 150 nm. The curve B means that C60 is used as the guest and the distribution depth is 60 nm. The curve C means that C60 is used as the guest and the distribution depth is 120 nm. FIG. 5 shows that the brightness of curve A degrades significantly. For 250 hours of operation, for example, the brightness of curve A is only about 75% while the brightness of curves B and C stays at 90%. Obviously, the reliability of the light emitting device according to an embodiment of the invention improves on that of the conventional light emitting device.

Embodiments of the invention utilize incorporating dopants, such as fullerene, into a hole-injection layer or a hole-transport layer to enhance hole mobility. Thus, the hole-injection layer and/or the hole-transport layer can be thickened without influencing the I-V characteristics.

Furthermore, the abovementioned light emitting device has comprehensive applications, for example, in flat panel display and portable display.

While the invention has been described by way of example and in terms of preferred embodiment, it is to be understood that the invention is not limited thereto. To the contrary, it is intended to cover various modifications and the advantages would be apparent to those skilled in the art. Therefore, the scope of the appended claims should be accorded the broadest interpretation so as to encompass all such modifications.

What is claimed is:

1. An organic light emitting device, comprising:
an anode;
a cathode; and
a complex emitting layer, disposed between the anode and the cathode, comprising:
a host, with a first energy level of a valence band, for use in a hole-injection layer or a hole-transport layer; and
a guest, with a second energy level of a conduction band, for doping the host;
wherein the difference between the first and second energy levels is less than 2.5 eV.

2. The organic light emitting device as claimed in claim 1, wherein the guest is organic material.

3. The organic light emitting device as claimed in claim 2, wherein the organic material is Alq.

4. The organic light emitting device as claimed in claim 1, wherein the guest is inorganic material.

5. The organic light emitting device as claimed in claim 4, wherein the inorganic material is fullerene.

6. The organic light emitting device as claimed in claim 5, wherein the fullerene comprises C60, C70, C76, C78, C82, C84, C90, C96 or derivatives thereof.

7. The organic light emitting device as claimed in claim 1, wherein the molecular doping concentration is between 0.1% and 50%.

8. The organic light emitting device as claimed in claim 1, wherein the molecular doping concentration is between 1% and 20%.

9. The organic light emitting device as claimed in claim 1, wherein the guest has a distribution depth of 5 to 500 nm in the host.

10. A flat panel display incorporating the organic light emitting device of the claim 1.

11. A portable display incorporating the organic light emitting device of the claim 1.
